(19) United States
(12) Patent Application Publication
(10) Pub. No.: US 2008/0251863 A1
(43) Pub. Date: Oct. 16, 2008

(54) HIGH-VOLTAGE RADIO-FREQUENCY POWER DEVICE

(76) Inventors: Sheng-Yi Huang, Hsinchu County (TW); Cheng-Chou Hung, Hsinchu County (TW); Yu-Chia Chen, Taipei City (TW); Chin-Lan Tseng, Miaoli County (TW); Chih-Yuh Tzeng, Hsinchu City (TW); Victor-Chiang Liang, Hsin-Chu City (TW); Chun-Yi Lin, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/735,447

(22) Filed: Apr. 14, 2007

(51) Int. Cl. H01L 29/76

(52) U.S. Cl. 257/409; 257/E29.226

(57) ABSTRACT

A high-voltage RF power device includes a plurality of serially connected transistors. Each transistor includes a gate finger disposed on a substrate, a gate dielectric layer, a drain structure disposed on one side of the gate finger, and an N+ source region on the other side of the gate finger. The drain structure includes an N+ doping region encompassed by a shallow trench isolation (STI) structure, and an N well directly underneath the STI structure and the N+ doping region.

### BACKGROUND OF THE INVENTION

1. Field of the Invention

The present invention relates generally to the field of CMOS transistor technology and, more particularly, to a high-voltage radio-frequency (RF) power device having improved power performance, high-frequency characteristics and higher breakdown voltage. The present invention high-voltage RF power device is compatible with advanced core-CMOS processes.

2. Description of the Prior Art

In recent years, advanced CMOS technologies have been investigated and pushed to perform well in RF areas, like in wireless systems such as Bluetooth applications, WLANs and ultra-wide band (UWB). Silicon integrated power CMOS technology is inherently superior in terms of cost, compact size, and short time-to-market. Hence, the development of suitable power transistors for system-on-a-chip (SoC) is indispensable.

SoC is an idea of integrating all components of a computer or other electronic system into a single integrated circuit chip. It may contain micro processing core, MPEG core, memory, digital/analog circuits, mixed-signal circuits, and often radio-frequency functions—all on one chip. SoC is believed to be more cost effective since it increases the yield of the fabrication and also its packaging is less complicated.

As known in the art, power transistor devices with higher breakdown voltage are beneficial to tolerate higher power delivery and have higher power-added efficiency (PAE). However, the drawback of current core-CMOS technology showing a limitation of lower breakdown output voltage, leading to limited RF power applications.

Therefore, there is a strong need in this industry to provide a high-voltage RF power device, which is suited for RF SoC applications and is fully compatible with advanced core-CMOS processes such as 0.13 micron or below, cost-effective, with higher breakdown voltage and output resistance, improved RF power performance and high-frequency characteristics.

### SUMMARY OF THE INVENTION

It is one object of the present invention to provide a high-voltage RF power device having improved power performance, better high-frequency characteristics and higher breakdown voltage, and the high-voltage RF power device is compatible with advanced core-CMOS processes, such that the high-voltage RF power device is suited for RF SoC applications.

According to one aspect of this invention, a high-voltage RF power device comprises a first transistor and a second transistor serial connected with the first transistor. The first transistor comprises a first gate finger on a semiconductor substrate, a first gate dielectric layer between the first gate finger and the semiconductor substrate, a first drain structure and a first N+ source doping region, wherein the first drain structure comprises a first N+ drain doping region, a first shallow trench isolation (STI) structure isolating the first N+ drain doping region, and a first N well encompassing the first N+ drain doping region, wherein the first N well is situated directly below the first STI structure. The second transistor comprises a second gate finger on the semiconductor substrate, a second gate dielectric layer between the second gate finger and the semiconductor substrate, a second drain structure and a second N+ source doping region, wherein the second drain structure comprises a second N+ drain doping region, a second STI structure isolating the second N+drain doping region, and a second N well encompassing the second N+ drain doping region, wherein the second N well is situated directly below the second STI structure. The first and second gate fingers are coupled to the same gate voltage signal, the first and second N+drain doping regions are coupled to the same drain voltage signal, and the first and second N+ source doping regions are coupled to the same source voltage signal.

According to another aspect of this invention, a high-voltage RF power device comprises a semiconductor substrate of a first conductivity type; a first gate finger on the semiconductor substrate; a first gate dielectric layer between the first gate finger and the semiconductor substrate; a first drain structure disposed on one side of the first gate finger, the first drain structure comprising a first drain doping region of a second conductivity type opposite to the first conductivity type, a first shallow trench isolation (STI) structure isolating the first drain doping region, and a first ion well encompassing the overlying first drain doping region, wherein the first ion well is situated directly below the first STI structure; a source doping region of the second conductivity type disposed on the other side of the first gate finger; a second gate finger on the semiconductor substrate, the second gate finger being adjacent to the source doping region; a second gate dielectric layer between the second gate finger and the semiconductor substrate; and a second drain structure comprises a second drain doping region of the second conductivity type, a second STI structure isolating the second drain doping region, and a second ion well encompassing the overlying second drain doping region, wherein the second ion well is situated directly below the second STI structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic diagram showing the layout of a high-voltage RF power device in accordance with the first preferred embodiment of this invention;

FIG. 2 is a schematic, cross-sectional diagram taken along line I-I′ of FIG. 1;

FIG. 3 is a schematic diagram showing the layout of a high-voltage RF power device in accordance with the second preferred embodiment of this invention;

FIG. 4 is a schematic, cross-sectional diagram taken along line II-II′ of FIG. 3;

FIG. 5 is a schematic diagram showing the layout of a high-voltage RF power device in accordance with the third preferred embodiment of this invention;

FIG. 6 is a schematic, cross-sectional diagram taken along line III-III′ of FIG. 5;

FIG. 7 is a schematic diagram showing the layout of a high-voltage RF power device in accordance with the fourth preferred embodiment of this invention;

FIG. 8 is a schematic diagram showing the layout of a high-voltage RF power device in accordance with the fifth preferred embodiment of this invention;

FIG. 9 is a schematic, cross-sectional diagram taken along line IV-IV′ of FIG. 8; and

FIG. 10 is a schematic diagram showing the layout of a high-voltage RF power device in accordance with the sixth preferred embodiment of this invention.

### DETAILED DESCRIPTION

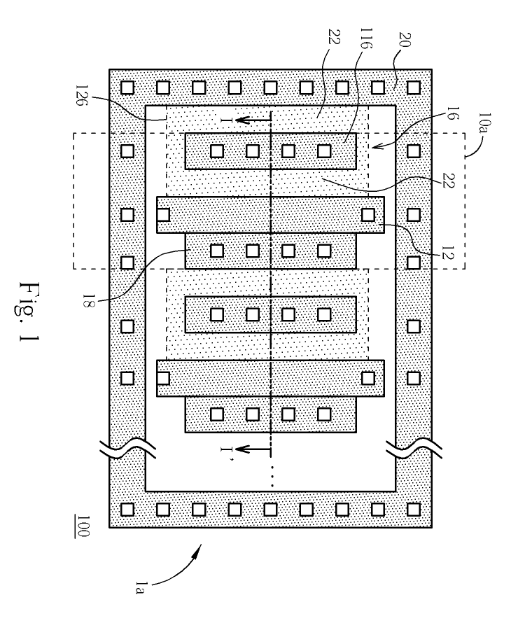

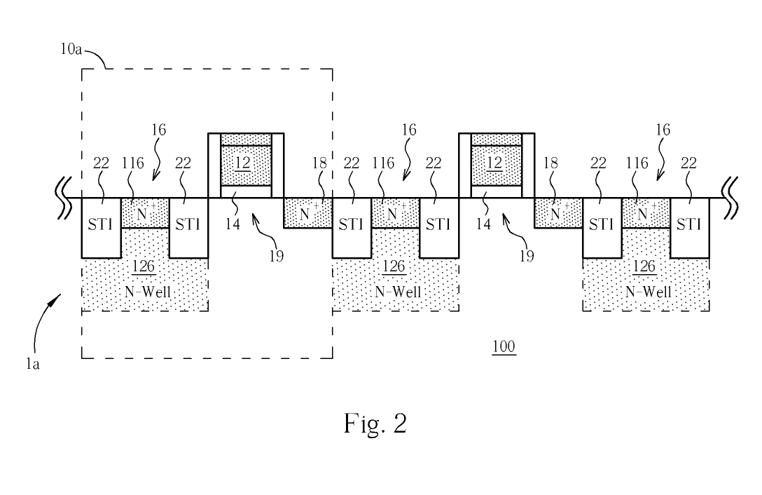

Please refer to FIG. 1 and FIG. 2, wherein FIG. 1 is a schematic diagram showing the layout of a high-voltage RF power device in accordance with the first preferred embodiment of this invention, and FIG. 2 is a schematic, cross-sectional diagram taken along line I-I′ of FIG. 1.

As shown in FIG. 1 and FIG. 2, the high-voltage RF power device 1a comprises a plurality of serial-connected unit transistors 10a (one of the serial-connected unit transistors 10a is indicated by the dashed line). The high-voltage RF power device 1a further comprises a guard ring 20 encompassing the plural unit transistors 10a. According to this invention, the guard ring 20 is an annular P+ doping region implanted into a P type silicon substrate 100 and is often grounded.

Each unit transistor 10a comprises a gate finger 12, a gate dielectric layer 14 between the gate finger 12 and the P type silicon substrate 100, a drain structure 16 and an N+ source doping region 18. A gate channel 19 is defined under the gate finger 12. The drain structure 16 comprises an N+ drain doping region 116, a shallow trench isolation (STI) structure 22 and an N⁻ ion well 126 encompassing the N+ drain doping region 116. The gate finger 12 may be composed of polysilicon, silicide or metals. Spacers may be formed on sidewalls of the gate finger 12.

The STI structure 22 is formed in the P type silicon substrate 100 and is used to isolate the N+ drain doping region 116 from the gate finger 12. The STI structure 22 surrounds the N+ drain doping region 116. The N⁻ ion well 126 is situated directly under the N+ drain doping region 116 and the STI structure 22.

As previously mentioned, the plural unit transistors 10a are serial connected to each other. According to the first preferred embodiment of this invention, the drain structure 16 of one unit transistor 10a borders the N+ source doping region 18 of another.

Preferably, the doping concentration of the N+ drain doping region 116 is about 1 E20 atoms/cm³, and the doping concentration of the N⁻ ion well 126 is about 1 E18 atoms/cm³. The N⁻ ion well 126 forms a high resistance drift region between the gate channel 19 and the N+ drain doping region 116 (drain terminal). Thus, owing to the N⁻ ion well 126, the output resistance of the RF power device is increased.

According to the first preferred embodiment of this invention, the N⁻ ion well 126 of one unit transistor 10a does not overlap or electrically connect with the N+ source doping region 18 of the neighboring unit transistor. According to the experimental results, the aforesaid non-overlapping configuration provides higher breakdown voltage BV_{DS} (up to 4.3V on 0.13 μm gate length basis).

However, in another embodiment, the N⁻ ion well 126 of one unit transistor 10a may exceed the STI region by diffusion and may overlap or electrically connect with the N+ source doping region 18 of the neighboring unit transistor. Such overlapping configuration provides a breakdown voltage BV_{DS} up to 4.1V (on 0.13 μm gate length basis).

According to the first preferred embodiment, the gate fingers 12 of the plural unit transistors 10a are coupled to the same gate voltage signal through interconnection, the N+ source doping regions 18 of the plural unit transistors 10a are coupled to the same source voltage signal, and N+ drain doping regions 116 of the plural unit transistors 10a are coupled to the same drain voltage signal.

Since the present invention high-voltage RF power device 1a has the drain structure 16 with the N− ion well 126 for providing a higher output resistance, therefore, the breakdown voltage BV_{DS} of the high-voltage RF power device 1a can be increased up to 4.3V (gate length=0.13 μm; gate bias V_{GS}=1.2V).

The experimental results exhibit that the cutoff frequency and maximum oscillation frequency of the present invention high-voltage RF power device 1a are 68 GHz and 87 GHz, respectively, and has a power gain of 16.8 dBm. In addition, the present invention high-voltage RF power device 1a has an output power of 15.91 dBm (at 2.4 GHz) and a power-added efficiency (PAE) of 43.5%. The experimental results also exhibit improved RF linearity. The OIP3 is 28.6 dBm (at 2.4 GHz).

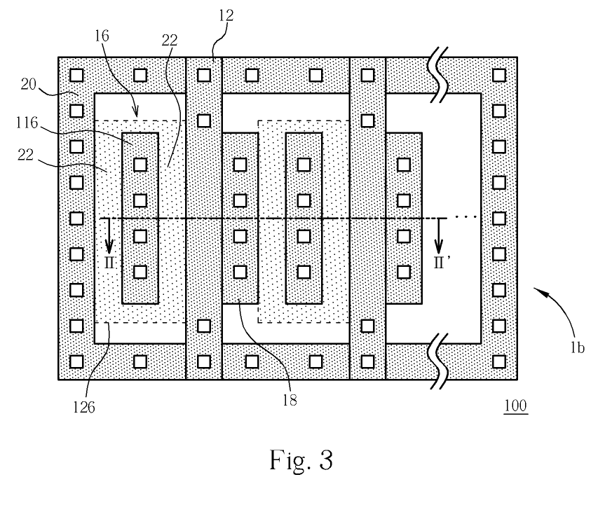

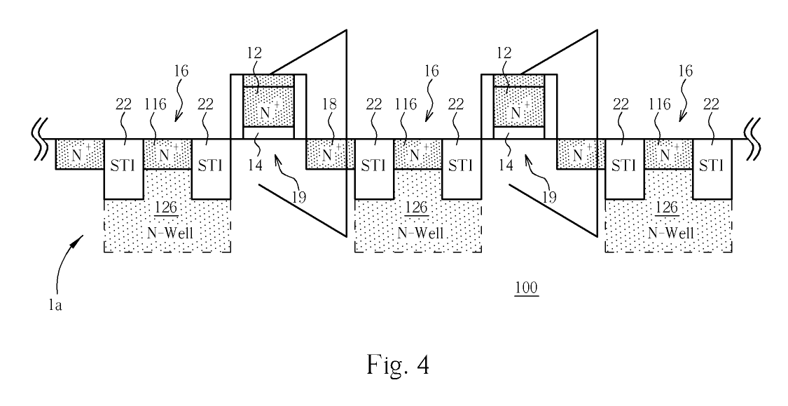

Please refer to FIG. 3 and FIG. 4, wherein FIG. 3 is a schematic diagram showing the layout of a high-voltage RF power device in accordance with the second preferred embodiment of this invention, and FIG. 4 is a schematic, cross-sectional diagram taken along line II-II′ of FIG. 3.

The difference between the high-voltage RF power device 1b of FIG. 3 and the high-voltage RF power device 1a of FIG. 1 is that the gate fingers 12 of the plurality of unit transistors of the high-voltage RF power device 1b further extend to the guard ring and are coupled to the P type silicon substrate 100 by connecting the gate fingers 12 with the guard ring 20 so as to form a dynamic threshold configuration. Such high-voltage RF power device 1b depicted in FIG. 3 and FIG. 4 is also referred to as series-parallel dynamic threshold high-voltage (DTHV) RF power device.

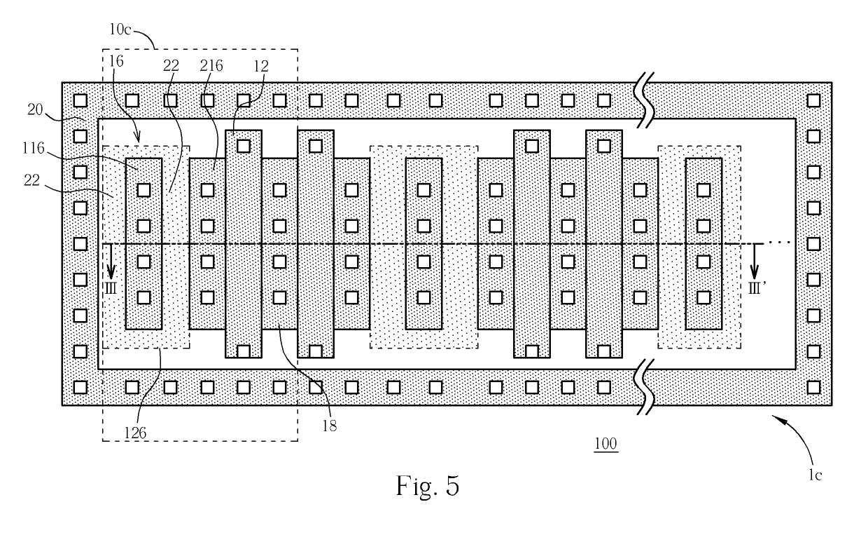

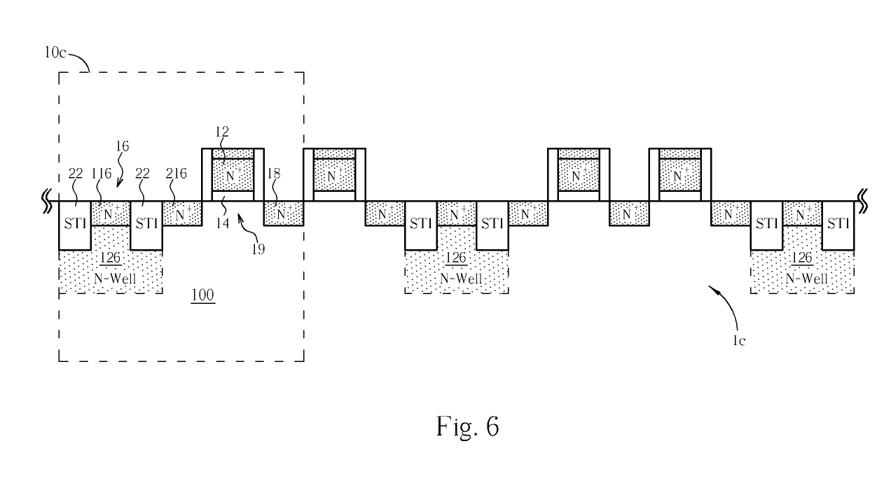

Please refer to FIG. 5 and FIG. 6, wherein FIG. 5 is a schematic diagram showing the layout of a high-voltage RF power device in accordance with the third preferred embodiment of this invention, and FIG. 6 is a schematic, cross-sectional diagram taken along line III-III′ of FIG. 5.

As shown in FIG. 5 and FIG. 6, the high-voltage RF power device 1c comprises a plurality of serial-connected unit transistors 10c (one of the serial-connected unit transistors 10c is indicated by the dashed line). Likewise, each unit transistor 10c comprises a gate finger 12, a gate dielectric layer 14 between the gate finger 12 and the P type silicon substrate 100, a drain structure 16 and an N+ source doping region 18. A gate channel 19 is defined under the gate finger 12. The drain structure 16 comprises an N+ drain doping region 116, a shallow trench isolation (STI) structure 22 and an N⁻ ion well 126 encompassing the N+ drain doping region 116.

The high-voltage RF power device 1c further comprises a guard ring 20 encompassing the plural unit transistors 10c. According to this invention, the guard ring 20 is an annular P+ doping region implanted into a P type silicon substrate 100 and is often grounded.

Each unit transistor 10c further comprises an N+ doping region 216 that is disposed between the drain structure 16 and the gate finger 12. The STI structure 22 isolates the N+ drain doping region 116 from the N+ doping region 216. This is one difference between the third preferred embodiment and the first preferred embodiment. That is, the unit transistor 10c of FIG. 6 has an additional N+ doping region 216 compared with the unit transistor 10a of FIG. 2. The high-voltage RF power device 1c may be referred to as a pseudo-drain high-voltage RF power device.

Likewise, the STI structure 22 is formed in the P type silicon substrate 100 and is used to isolate the N+ drain doping region 116. The STI structure 22 surrounds the N+ drain doping region 116. The N⁻ ion well 126 is situated directly under the N+ drain doping region 116 and the STI structure 22.

Preferably, the doping concentration of the N+ drain doping region 116 is about 1 E20 atoms/cm³, and the doping concentration of the N⁻ ion well 126 is about 1 E18 atoms/cm³. The N⁻ ion well 126 forms a high resistance drift region between the gate channel 19 and the N+ drain doping region 116. According to this invention, the N⁻ ion well 126 does not overlap or electrically connect with the N+ doping region 216.

Another difference between the third preferred embodiment and the first preferred embodiment is the serial connection configuration of the plural unit transistors. As shown in FIG. 6, each unit transistor 10c is serial connected to the neighboring unit transistor by sharing the N+ source doping region 18 or sharing the drain structure 16. This renders two connected unit transistors 10c mirror symmetric to each other.

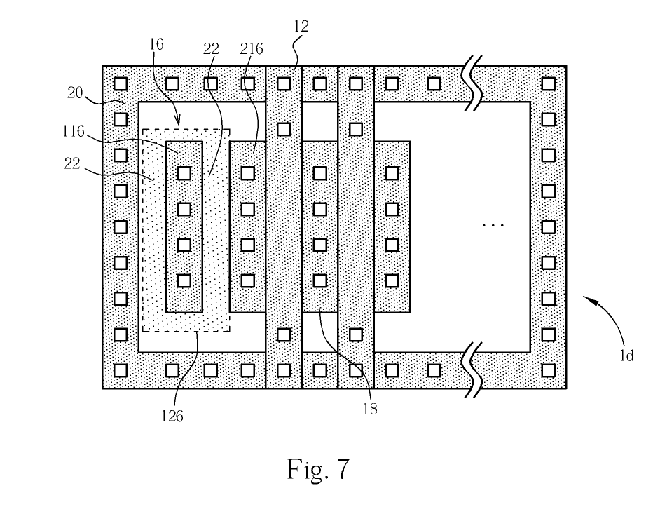

FIG. 7 is a schematic diagram showing the layout of a high-voltage RF power device 1d in accordance with the fourth preferred embodiment of this invention. The difference between the high-voltage RF power device 1d of FIG. 7 and the high-voltage RF power device 1a of FIG. 1 is that the gate fingers 12 of the plurality of unit transistors of the high-voltage RF power device 1d further extend to the guard ring 20 and are coupled to the P type silicon substrate 100 by connecting the gate fingers 12 with the guard ring 20 so as to form a dynamic threshold configuration.

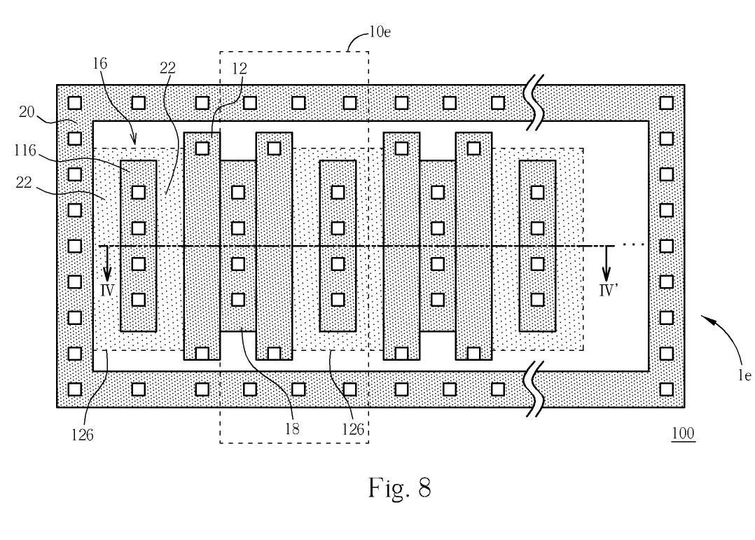

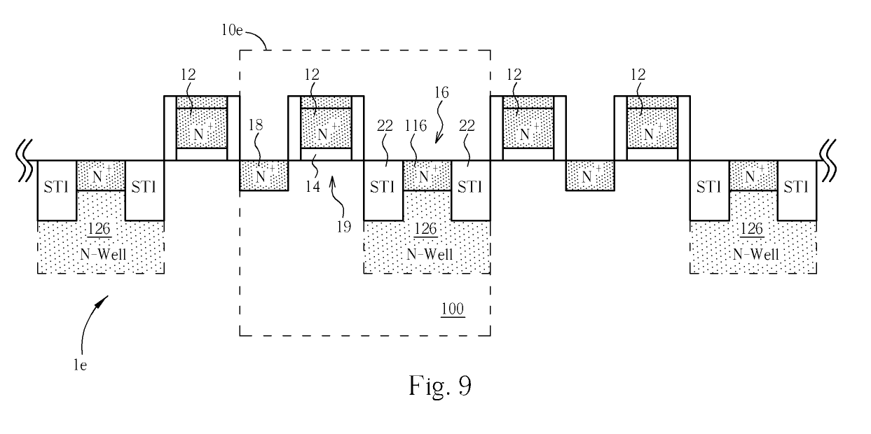

Please refer to FIG. 8 and FIG. 9, wherein FIG. 8 is a schematic diagram showing the layout of a high-voltage RF power device in accordance with the fifth preferred embodiment of this invention, and FIG. 9 is a schematic, cross-sectional diagram taken along line IV-IV′ of FIG. 8.

As shown in FIG. 8 and FIG. 9, the high-voltage RF power device 1e comprises a plurality of serial-connected unit transistors 10e (one of the serial-connected unit transistors 10e is indicated by the dashed line). Each unit transistor 10e comprises a gate finger 12, a gate dielectric layer 14 between the gate finger 12 and the P type silicon substrate 100, a drain structure 16 and an N+ source doping region 18. A gate channel 19 is defined under the gate finger 12. The drain structure 16 comprises an N+ drain doping region 116, STI structure 22 and an N⁻ ion well 126 encompassing the N+ drain doping region 116.

The high-voltage RF power device 1e further comprises a guard ring 20 encompassing the plural unit transistors 10e. According to this invention, the guard ring 20 is an annular P+ doping region implanted into a P type silicon substrate 100 and is often grounded.

The STI structure 22 is formed in the P type silicon substrate 100 and is used to isolate the N+ drain doping region 116. The STI structure 22 surrounds the N+ drain doping region 116. The N⁻ ion well 126 is situated directly under the N+ drain doping region 116 and the STI structure 22.

According to this invention, the doping concentration of the N+ drain doping region 116 is preferably about 1 E20 atoms/cm³, and the doping concentration of the N⁻ ion well 126 is about 1 E18 atoms/cm³. The N⁻ ion well 126 forms a high resistance drift region between the gate channel 19 and the N+ drain doping region 116. According to this invention, the N⁻ ion well 126 does not overlap or electrically connect with the N+ source doping region 18.

The difference between the fifth preferred embodiment and the first preferred embodiment is the serial connection configuration of the plural unit transistors. As shown in FIG. 9, each unit transistor 10e is serial connected to the neighboring unit transistor by sharing the N+ source doping region 18 or sharing the drain structure 16. This renders two connected unit transistors 10e mirror symmetric to each other.

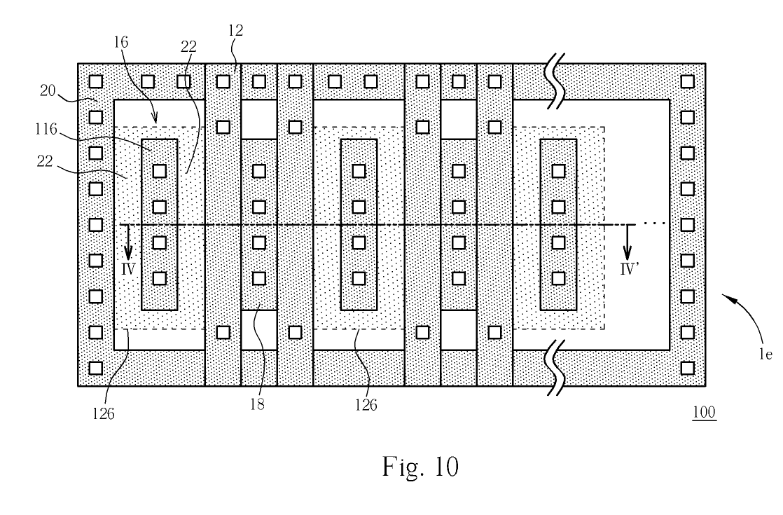

FIG. 10 is a schematic diagram showing the layout of a high-voltage RF power device 1f in accordance with the sixth preferred embodiment of this invention. The difference between the high-voltage RF power device 1f of FIG. 10 and the high-voltage RF power device 1a of FIG. 1 is that the gate fingers 12 of the plurality of unit transistors of the high-voltage RF power device 1f further extend to the guard ring 20 and are coupled to the P type silicon substrate 100 by connecting the gate fingers 12 with the guard ring 20 so as to form a dynamic threshold configuration.

The advantages and improvements of this invention at least include:

(1) No extra photo mask and cost is required since the present invention high-voltage RF power device is fully compatible with CMOS processes.

(2) The series-parallel configuration of the present invention high-voltage RF power device is suited for low power or medium power wireless applications (10˜20 dBm).

(3) The present invention high-voltage RF power device exhibits a high output resistance (Rₒᵤₜ) and an increased (˜40%) breakdown voltage.

(4) The power characteristics are improved. The RF linearity increases about 10 dBm for P_{1dB} and IIP3 (OIP3).

Those skilled in the art will readily observe that numerous modifications and alterations of the device and method may be made while retaining the teachings of the invention.

What is claimed is:

1. A high-voltage radio-frequency (RF) power device, comprising:
a first transistor comprising: a first gate finger on a semiconductor substrate, a first gate dielectric layer between the first gate finger and the semiconductor substrate, a first drain structure and a first N+ source doping region, wherein the first drain structure comprises a first N+ drain doping region, a first shallow trench isolation (STI) structure isolating the first N+ drain doping region, and a first N well encompassing the first N+ drain doping region, wherein the first N well is situated directly below the first STI structure; and
a second transistor serial connecting with the first transistor, the second transistor comprising: a second gate finger on the semiconductor substrate, a second gate dielectric layer between the second gate finger and the semiconductor substrate, a second drain structure and a second N+ source doping region, wherein the second drain structure comprises a second N+ drain doping region, a second STI structure isolating the second N+ drain doping region, and a second N well encompassing the second N+ drain doping region, wherein the second N well is situated directly below the second STI structure;
wherein the first and second gate fingers are coupled to the same gate voltage signal, the first and second N+ drain doping regions are coupled to the same drain voltage signal, and the first and second N+ source doping regions are coupled to the same source voltage signal.

2. The high-voltage RF power device according to claim 1 further comprising a guard ring surrounding the first and second transistors.

3. The high-voltage RF power device according to claim 2 wherein the guard ring is an annular P+ doping region.

4. The high-voltage RF power device according to claim 2 wherein the guard ring is connected to ground.

5. The high-voltage RF power device according to claim 1 wherein the semiconductor substrate is a P type silicon substrate.

6. The high-voltage RF power device according to claim 1 wherein the first N+ source doping region borders the second drain structure.

7. The high-voltage RF power device according to claim 1 wherein the second N well does not overlap with the first N+ source doping region.

8. The high-voltage RF power device according to claim 1 wherein the first STI structure is situated between the first N+ drain doping region.

9. The high-voltage RF power device according to claim 1 wherein the second STI structure is situated between the second N+ drain doping region.

10. The high-voltage RF power device according to claim 1 wherein the first and second gate fingers are coupled with the semiconductor substrate.

11. A high-voltage radio-frequency (RF) power device, comprising:
a semiconductor substrate of a first conductivity type;
a first gate finger on the semiconductor substrate;
a first gate dielectric layer between the first gate finger and the semiconductor substrate;
a first drain structure disposed on one side of the first gate finger, the first drain structure comprising a first drain doping region of a second conductivity type opposite to the first conductivity type, a first shallow trench isolation (STI) structure isolating the first drain doping region, and a first ion well encompassing the overlying first drain doping region, wherein the first ion well is situated directly below the first STI structure;
a source doping region of the second conductivity type disposed on the other side of the first gate finger;
a second gate finger on the semiconductor substrate, the second gate finger being adjacent to the source doping region;
a second gate dielectric layer between the second gate finger and the semiconductor substrate; and
a second drain structure comprises a second drain doping region of the second conductivity type, a second STI structure isolating the second drain doping region, and a second ion well encompassing the overlying second drain doping region, wherein the second ion well is situated directly below the second STI structure.

12. The high-voltage RF power device according to claim 11 further comprising a guard ring surrounding the high-voltage RF power device.

13. The high-voltage RF power device according to claim 12 wherein the guard ring is an annular P+ doping region.

14. The high-voltage RF power device according to claim 12 wherein the guard ring is connected to ground.

15. The high-voltage RF power device according to claim 11 wherein the semiconductor substrate is a P type silicon substrate.

16. The high-voltage RF power device according to claim 11 further comprising a pseudo-drain doping region disposed between the first gate finger and the first drain structure and between the second gate finger and the second drain structure.

17. The high-voltage RF power device according to claim 11 wherein the first and second ion wells have the second conductivity type.

18. The high-voltage RF power device according to claim 11 wherein the first conductivity type is P type and the second conductivity type is N type.

19. The high-voltage RF power device according to claim 11 wherein the first and second gate fingers are coupled to the same gate voltage signal, and the first and second drain doping regions are coupled to the same drain voltage signal.
